(19) United States
(12) Patent Application Publication
(10) Pub. No.: US 2025/0076047 A1
(43) Pub. Date: Mar. 6, 2025

(54) SENSOR, SENSOR SYSTEM, AND ELECTRONIC DEVICE

(71) Applicant: KABUSHIKI KAISHA TOSHIBA, Tokyo (JP)

(72) Inventors: Daiki ONO, Yokohama Kanagawa (JP); Hideaki MURASE, Yokohama Kanagawa (JP); Fumito MIYAZAKI, Yokohama Kanagawa (JP); Yasushi TOMIZAWA, Fuchu Tokyo (JP); Kei MASUNISHI, Kawasaki Kanagawa (JP); Kengo UCHIDA, Kawasaki Kanagawa (JP); Etsuji OGAWA, Kawasaki Kanagawa (JP); Fumitaka ISHIBASHI, Sumida Tokyo (JP); Jumpei OGAWA, Kawasaki Kanagawa (JP)

(73) Assignee: KABUSHIKI KAISHA TOSHIBA, Tokyo (JP)

(21) Appl. No.: 18/731,984

(22) Filed: Jun. 3, 2024

(30) Foreign Application Priority Data
Aug. 29, 2023 (JP) 2023-139067

(51) Int. Cl. G01C 19/5705

(52) U.S. Cl. CPC G01C 19/5705

(57) ABSTRACT

According to one embodiment, a sensor includes a base including a first face, a fixed portion fixed to the first face, a movable portion supported by the fixed portion, a first fixed electrode, and a first opposing fixed electrode. The fixed portion includes a first center in a first plane parallel to the first face. The movable portion includes first and second annular portions. The first fixed electrode includes first and second regions. The first opposing fixed electrode includes first and second opposing regions. The first region is provided between the second annular portion and the first annular portion. The first opposing region is provided between the second annular portion and the first region. The second region is provided between the second annular portion and the first annular portion. The second opposing region is provided between the second annular portion and the second region.

### CROSS-REFERENCE TO RELATED APPLICATIONS

This application is based upon and claims the benefit of priority from Japanese Patent Application No. 2023-139067, filed on Aug. 29, 2023; the entire contents of which are incorporated herein by reference.

### FIELD

Embodiments described herein relate generally to a sensor, a sensor system, and an electronic device.

### BACKGROUND

For example, there are sensors having a MEMS (Micro Electro Mechanical Systems) structure. In some cases, electronic devices and the like are controlled based on information obtained by sensors. It is desired to improve the characteristics of sensors.

### BRIEF DESCRIPTION OF THE DRAWINGS

FIG. 1 is a schematic plan view illustrating a sensor according to a first embodiment;

FIG. 2 is a schematic plan view illustrating a part of the sensor according to the first embodiment;

FIG. 3 is a schematic cross-sectional view illustrating the sensor according to the first embodiment;

FIG. 4 is a schematic cross-sectional view illustrating the sensor according to the first embodiment;

FIG. 5 is a schematic cross-sectional view illustrating the sensor according to the first embodiment;

FIG. 6 is a schematic cross-sectional view illustrating the sensor according to the first embodiment;

FIG. 7 is a schematic plan view illustrating a part of the sensor according to the first embodiment;

FIG. 8 is a schematic plan view illustrating a sensor according to the first embodiment;

FIG. 9 is a schematic plan view illustrating a sensor according to the first embodiment;

FIG. 10 is a schematic plan view illustrating a sensor according to the first embodiment;

FIG. 11 is a schematic diagram illustrating an electronic device according to a second embodiment;

FIGS. 12A to 12H are schematic views illustrating applications of the electronic device according to the embodiment; and

FIGS. 13A and 13B are schematic views illustrating applications of the sensor according to the embodiment.

### DETAILED DESCRIPTION

According to one embodiment, a sensor includes a base including a first face, a fixed portion fixed to the first face, a movable portion supported by the fixed portion, a first fixed electrode, and a first opposing fixed electrode. A first gap is provided between the first face and the movable portion. The fixed portion includes a first center in a first plane parallel to the first face. The movable portion includes a first annular portion and a second annular portion. The first fixed electrode includes a first region and a second region. The first opposing fixed electrode includes a first opposing region and a second opposing region. The first region is provided between the second annular portion and the first annular portion. The first opposing region is provided between the second annular portion and the first region. The second region is provided between the second annular portion and the first annular portion. The second opposing region is provided between the second annular portion and the second region. A first region width of the first region in a radial direction, which is parallel to the first plane and passes through the first center, is different from a second region width of the second region in the radial direction. A first opposing region width of the first opposing region in the radial direction is different from a second opposing region width of the second opposing region in the radial direction.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

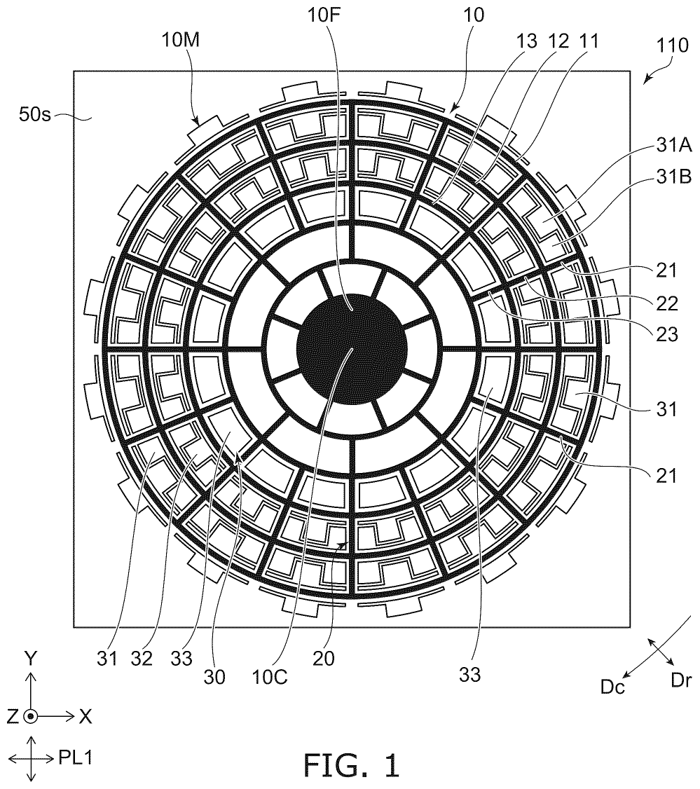

FIG. 1 is a schematic plan view illustrating a sensor according to a first embodiment.

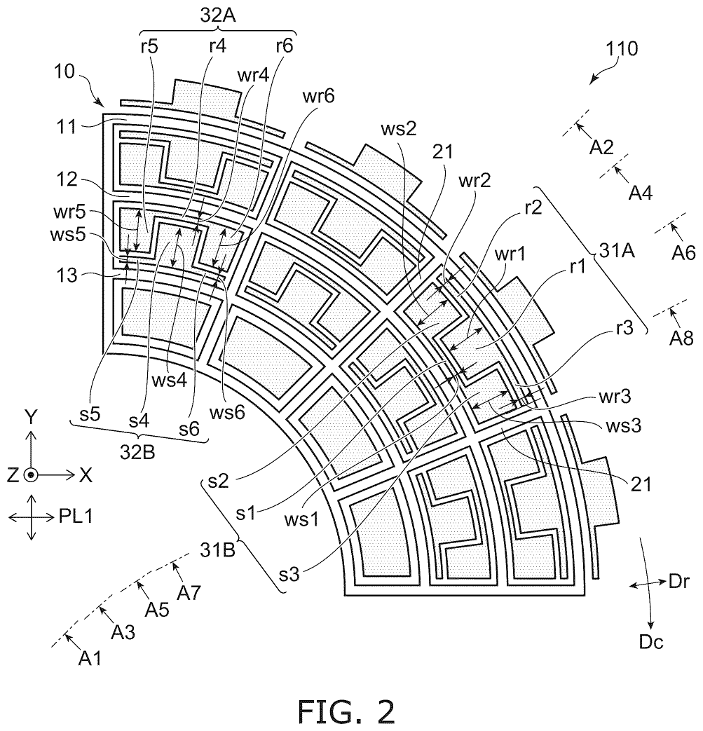

FIG. 2 is a schematic plan view illustrating a part of the sensor according to the first embodiment.

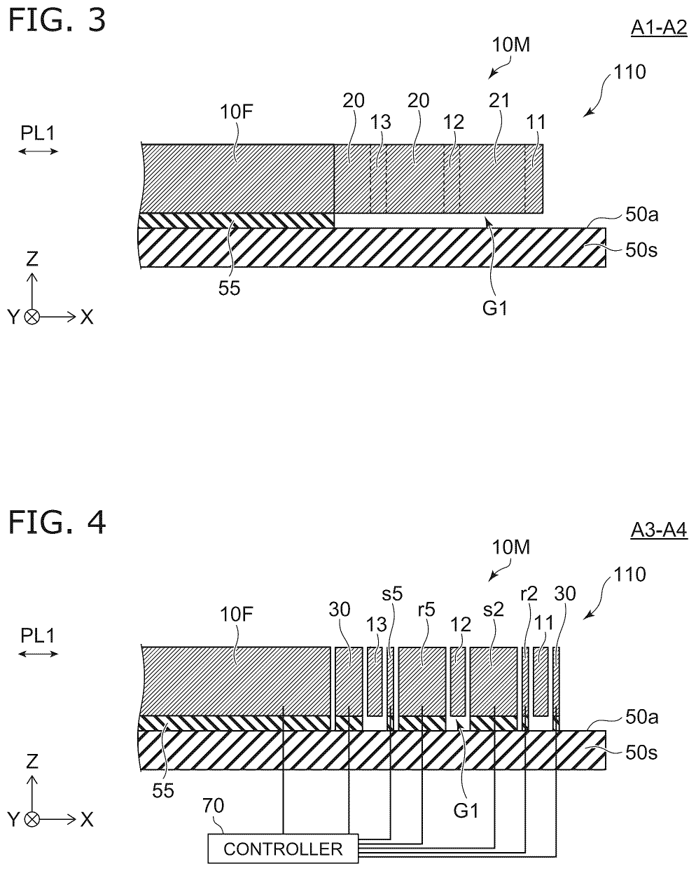

FIGS. 3 to 6 are schematic cross-sectional views illustrating the sensor according to the first embodiment.

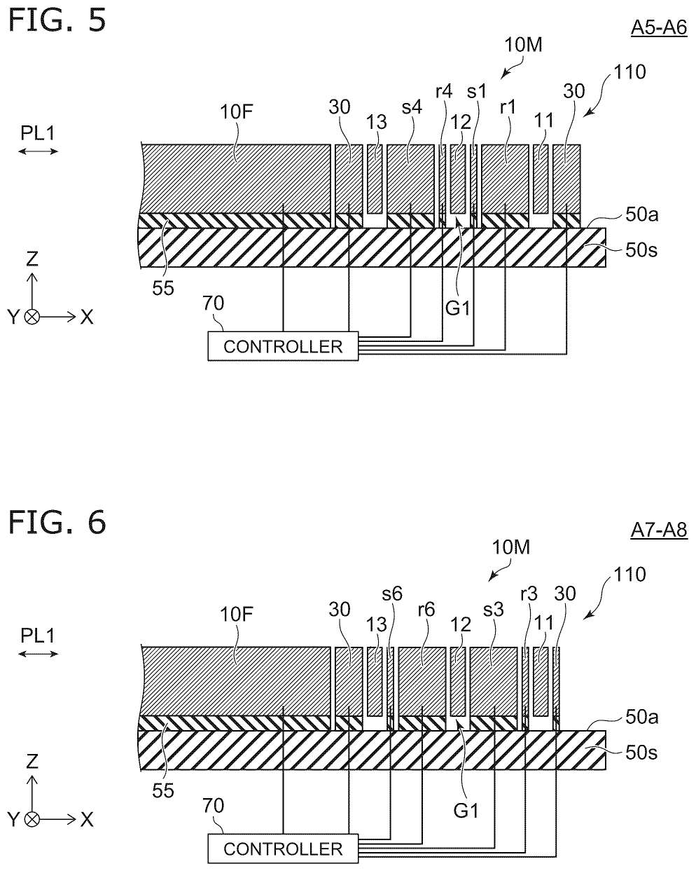

FIG. 3 is a sectional view taken along the line A1-A2 in FIG. 2. FIG. 4 is a sectional view taken along the line A3-A4 in FIG. 2. FIG. 5 is a sectional view taken along the line the A5-A6 in FIG. 2. FIG. 6 is a sectional view taken along the line A7-A8 in FIG. 2.

As shown in FIGS. 1 to 6, a sensor 110 according to the embodiment includes a base 50s, a fixed portion 10F, a movable portion 10M, a first fixed electrode 31A, and a first opposing fixed electrode 31B.

The base 50s includes a first face 50a. The fixed portion 10F is fixed to the first face 50a. The movable portion 10M is supported by the fixed portion 10F.

As shown in FIGS. 3 to 6, a first gap G1 is provided between the first face 50a and the movable portion 10M. For example, an insulating member 55 is provided on the first face 50a. The fixed portion 10F is provided on the insulating member 55. The insulating member 55 is not provided between the first face 50a and the movable portion 10M.

The movable portion 10M is electrically conductive. The movable portion 10M may include, for example, conductive silicon. The fixed portion 10F is electrically conductive. The fixed portion 10F may include, for example, conductive silicon. The fixed portion 10F is electrically connected to the movable portion 10M. The insulating member 55 may include, for example, silicon oxide.

As shown in FIG. 1, the fixed portion 10F includes a first center 10C in a first plane PL1 parallel to the first face 50a.

A direction perpendicular to the first plane PL1 is defined as a Z-axis direction. One direction perpendicular to the Z-axis direction is defined as an X-axis direction. A direction perpendicular to the Z-axis direction and the X-axis direction is defined as a Y-axis direction. The first plane PL1 is parallel to the X-Y plane.

The movable portion 10M includes a first annular portion 11 and a second annular portion 12. In this example, the second annular portion 12 is provided between the fixed portion 10F and the first annular portion 11. The first annular portion 11 may be provided between the fixed portion 10F and the second annular portion 12.

As shown in FIG. 2, the first fixed electrode 31A includes a first region r1 and a second region r2. The first opposing fixed electrode 31B includes a first opposing region s1 and a second opposing region s2. The first region r1 is provided between the second annular portion 12 and the first annular portion 11. The first opposing region s1 is provided between the second annular portion 12 and the first region r1. The second region r2 is provided between the second annular portion 12 and the first annular portion 11. The second opposing region s2 is provided between the second annular portion 12 and the second region r2.

As shown in FIG. 2, a width (length) of the first region r1 in a radial direction Dr parallel to the first plane PL1 and passing through the first center 10C is defined as a first region width wr1. a width (length) of the second region r2 in the radial direction Dr is defined as a second region width wr2. The first region width wr1 is different from the second region width wr2.

As shown in FIG. 2, a width (length) of the first opposing region s1 in the radial direction Dr is defined as a first opposing region width ws1. A width (length) of the second opposing region s2 in the radial direction Dr is defined as a second opposing region width ws2. The first opposing region width ws1 is different from the second opposing region width ws2.

In this example, the first region width wr1 is wider than the second region width wr2. The first opposing region width ws1 is narrower than the second opposing region width ws2.

For example, in the sensor 110, a plurality of fixed electrodes 30 are provided. For example, the plurality of fixed electrodes 30 are fixed to the first face 50a. The first fixed electrode 31A and the first opposing fixed electrode 31B are included in the plurality of fixed electrodes 30.

For example, a signal including an alternating component is applied between a part of the plurality of fixed electrodes 30 20 and the movable portion 10M. Thereby, the movable portion 10M vibrates. When an external force is applied to the movable portion 10M vibrating, the vibration state changes. By detecting a change in the vibration state, the applied external force can be detected. The change in the vibration state is detected as a 25 change in capacitance, for example. The change in the vibration state due to external forces are caused by, for example, Coriolis force. The change in the vibration state can be detected, for example, by another part of the plurality of fixed electrodes 30. The signal may be supplied by the controller 70, for example. For example, the controller 70 may detect the change in the vibration 30 state.

In the sensor 110, the first fixed electrode 31A faces the first annular portion 11. The first opposing fixed electrode 31B faces the second annular portion 12. By providing these electrodes in the narrow area between the second annular portion 12 and the first annular portion 11, the desired vibration can be obtained even when the size of the sensor 110 is reduced. The change in vibration state can be detected with high accuracy.

In the sensor 110, each of the first fixed electrode 31A and the first opposing fixed electrode 31B is provided with a wide region and a narrow region. For example, a connecting member (for example, a bonding wire) can be stably connected to the wide region. For example, even when the size of the sensor 110 is small, stable electrical connection can be obtained. For example, by stable electrical connection, highly accurate detection with suppressed noise can be obtained. According to the embodiment, a sensor with improved characteristics can be provided.

For example, the first region r1 and the second region r2 may be exchanged with each other. For example, in this case as well, a wide region and a narrow region are provided. For example, even when the size of the sensor 110 is small, stable electrical connection can be obtained. In the embodiment, the first annular portion 11 may be inside the second annular portion 12.

For example, in the sensor 110, one of a first condition and a second condition may be satisfied. In the first condition, the first region width wr1 is wider than the second region width wr2, and the first opposing region width ws1 is narrower than the second opposing region width ws2. In the second condition, the first region width wr1 is narrower than the second region width wr2, and the first opposing region width ws1 is wider than the second opposing region width ws2.

The second region r2 is continuous with the first region r1. The second opposing region s2 may be continuous with the first opposing region s1.

A direction from the second opposing region s2 to the first region r1 is along a circumferential direction Dc centered on the first center 10C. In the circumferential direction Dc, the second opposing region s2 faces the first region r1.

As shown in FIG. 2, the first fixed electrode 31A may further include a third region r3. The first opposing fixed electrode 31B may further include a third opposing region s3. The third region r3 is provided between the second annular portion 12 and the first annular portion 11. At least a part of the third opposing region s3 is provided between the second annular portion 12 and the third region r3. The first opposing region s1 is provided between the second opposing region s2 and the third opposing region s3. The first region width wr1 is different from a third region width wr3 of the third region r3 in the radial direction Dr. A first opposing region width ws1 is different from the third opposing region width ws3 of the third opposing region s3 in the radial direction Dr.

In this example, the first region width wr1 is wider than the second region width wr2. The first opposing region width ws1 is narrower than the second opposing region width ws2. The first region width wr1 is wider than the third region width wr3. The first opposing region width ws1 is narrower than the third opposing region width ws3.

The first region width wr1 may be narrower than the second region width wr2, and the first opposing region width ws1 may be wider than the second opposing region width ws2. In this case, the first region width wr1 is narrower than the third region width wr3, and the first opposing region width ws1 is wider than the third opposing region width ws3.

For example, in the circumferential direction Dc centered on the first center 10C, at least a part of the first region r1 is provided between the second region r2 and the third region r3. In the circumferential direction Dc, at least a part of the first opposing region s1 is provided between the second opposing region s2 and the third opposing region s3.

For example, a first ratio of a first absolute value of a difference between the first region width wr1 and the second region width wr2 to the first region width wr1 may be not less than 0.9 and not more than 30. A second ratio of a second absolute value of a difference between the first opposing region width ws1 and the second opposing region width ws2 to the first opposing region width ws1 may be not less than 0.9 and not more than 30.

The second region width wr2 may be not less than 0.05 times and not more than 30 the first region width wr1. The third region width wr3 may be not less than 0.8 times and not more than 1.2 times the second region width wr2.

The second opposing region width ws2 may be not less than 0.05 times and not more than 30 times the first opposing region width ws1. The third opposing region width ws3 may be not less than 0.8 times and not more than 1.2 times the second opposing region width ws2.

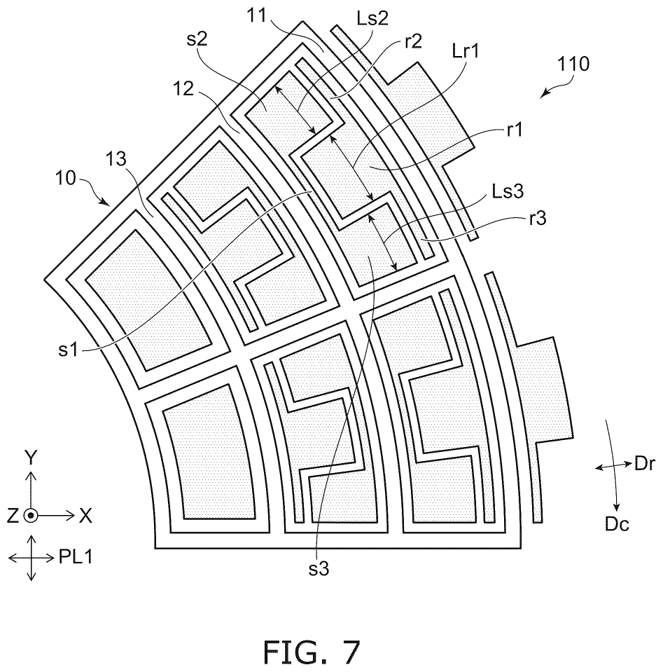

FIG. 7 is a schematic plan view illustrating a part of the sensor according to the first embodiment.

As shown in FIG. 7, in the sensor 110, a length of the second opposing region s2 in the circumferential direction Dc centered on the first center 10C is defined as a second opposing region length Ls2. A length of the third opposing region s3 in the circumferential direction Dc is defined as a third opposing region length Ls3. The second opposing region length Ls2 may be, for example, not less than 0.8 times and not more than 1.2 times the third opposing region length Ls3. For example, the second opposing region length Ls2 may be substantially the same as the third opposing region length Ls3, for example. Good symmetrical vibration can be obtained. For example, noise is suppressed. Highly accurate detection becomes easy.

A length of the first region r1 in the circumferential direction Dc is defined as a first region length Lr1. The first region length Lr1 may be, for example, not less than 0.1 times and not more than 10 times the second opposing region length Ls2. The first region length Lr1 may be, for example, not less than 0.8 times and not more than 1.2 times the second opposing region length Ls2.

As shown in FIG. 2, the movable portion 10M may include a plurality of first connect portions 21. The plurality of first connect portions 21 extend along the radial direction Dr. The plurality of first connect portions 21 connect the first annular portion 11 and the second annular portion 12. The first fixed electrode 31A and the first opposing fixed electrode 31B are provided between one of the plurality of first connect portions 21 and another one of the plurality of first connect portions 21. The other one of the plurality of first connect portions 21 is next to the one of the plurality of first connect portions 21 in the circumferential direction Dc.

As shown in FIG. 2, the sensor 110 may further include a second fixed electrode 32A and a second opposing fixed electrode 32B. The movable portion 10M may further include a third annular portion 13. The second annular portion 12 is provided between the third annular portion 13 and the first annular portion 11. In this example, the third annular portion 13 is provided between the fixed portion 10F and the second annular portion 12.

As shown in FIG. 2, the second fixed electrode 32A includes a fourth region r4 and a fifth region r5. The second opposing fixed electrode 32B includes a fourth opposing region s4 and a fifth opposing region s5. The fourth region r4 is provided between the third annular portion 13 and the second annular portion 12. The fourth opposing region s4 is provided between the third annular portion 13 and the fourth region r4. The fifth region r5 is provided between the third annular portion 13 and the second annular portion 12. The fifth opposing region s5 is provided between the third annular portion 13 and the fifth region r5.

A fourth region width wr4 of the fourth region r4 in the radial direction Dr is different from a fifth region width wr5 of the fifth region r5 in the radial direction Dr. A fourth opposing region width ws4 of the fourth opposing region s4 in the radial direction Dr is different from a fifth opposing region width ws5 of the fifth opposing region s5 in the radial direction Dr.

In each of the second fixed electrode 32A and the second opposing fixed electrode 32B, a wide region and a narrow region are provided. Electrical connections become easier. Noise is suppressed and highly accurate detection becomes possible.

In this example, the first region width wr1 is wider than the second region width wr2. The first opposing region width ws1 is narrower than the second opposing region width ws2. The fourth region width wr4 is narrower than the fifth region width wr5. The fourth opposing region width ws4 is wider than the fifth opposing region width ws5.

As shown in FIG. 2, the second fixed electrode 32A may further include a sixth region r6. The second opposing fixed electrode 32B may further include a sixth opposing region s6. The sixth region r6 is provided between the third annular portion 13 and the second annular portion 12. At least a part of the sixth opposing region s6 is provided between the third annular portion 13 and the sixth region r6. At least a part of the fourth region r4 is provided between the fifth region r5 and the sixth region r6.

The fourth region width wr4 is different from a sixth region width wr6 of the sixth region r6 in the radial direction Dr. The fourth opposing region width ws4 is different from a sixth opposing region width ws6 of the sixth opposing region s6 in the radial direction Dr.

In this example, the first region width wr1 is wider than the second region width wr2. The first opposing region width ws1 is narrower than the second opposing region width ws2. The fourth region width wr4 is narrower than the fifth region width wr5. The fourth opposing region width ws4 is wider than the fifth opposing region width ws5. The fourth region width wr4 is narrower than the fifth region width wr5. The fourth opposing region width ws4 is wider than the fifth opposing region width ws5. The fourth region width wr4 is narrower than the sixth region width wr6. The fourth opposing region width ws4 is wider than the sixth opposing region width ws6.

For example, the fifth region r5 is provided between the fifth opposing region s5 and the second region r2. For example, the second opposing region s2 is provided between the fifth region r5 and the second region r2.

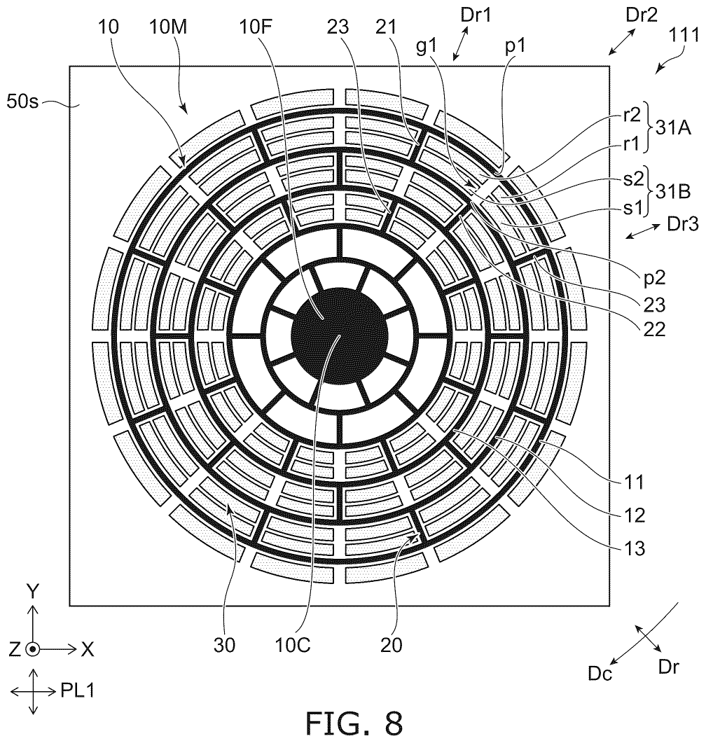

FIG. 8 is a schematic plan view illustrating a sensor according to the first embodiment.

As shown in FIG. 8, in a sensor 111 according to the embodiment, the configurations of the first fixed electrode 31A and the first opposing fixed electrode 31B are different from the configuration in the sensor 110. The configuration of the sensor 111 except for this may be the same as the configuration of the sensor 110.

The sensor 111 also includes the base 50s, the fixed portion 10F, the movable portion 10M, the first fixed electrode 31A, and the first opposing fixed electrode 31B. The first gap G1 is provided between the first face 50a of the base 50s and the movable portion 10M (see FIGS. 3 to 6). As shown in FIG. 8, the fixed portion 10F includes the first center 10C in the first plane PL1 parallel to the first face 50a.

The movable portion 10M includes the plurality of annular portions 10 and the plurality of connect portions 20. The plurality of annular portions 10 are provided around the fixed portion 10F with the first center 10C as the center. The plurality of annular portions 10 include the first annular portion 11, the second annular portion 12, and the third annular portion 13. The second annular portion 12 is provided between the fixed portion 10F and the first annular portion 11. The third annular portion 13 is provided between the fixed portion 10F and the second annular portion 12.

The plurality of connect portions 20 include the first connect portion 21, a second connect portion 22, and a third connect portion 23. The first connect portion 21 is provided between the second annular portion 12 and the first annular portion 11 and connects the second annular portion 12 and the first annular portion 11. The first connect portion 21 is along a first radial direction Dr1. The first radial direction Dr1 passes through the first center 10C and is along the first plane PL1. The second connect portion 22 is provided between the third annular portion 13 and the second annular portion 12 and connects the third annular portion 13 and the second annular portion 12. The second connect portion 22 is along a second radial direction Dr2. The second radial direction Dr2 passes through the first center 10C and is along the first plane PL1. The third connect portion 23 is provided between the second annular portion 12 and the first annular portion 11 and connects the second annular portion 12 and the first annular portion 11. The third connect portion 23 is along a third radial direction Dr3. The third radial direction Dr3 passes through the first center 10C and is along the first plane PL1.

The second radial direction Dr2 crosses the first radial direction Dr1. The third radial direction Dr3 crosses the first radial direction Dr1 and the second radial direction Dr2. An angle (first angle) between the second radial direction Dr2 and the first radial direction Dr1 is smaller than an angle (second angle) between the third radial direction Dr3 and the first radial direction Dr1. In this example, the first angle is substantially ½ of the second angle.

The first fixed electrode 31A includes the first region r1 and the second region r2. The first opposing fixed electrode 31B includes the first opposing region s1 and the second opposing region s2. The first region r1 is provided between the second annular portion 12 and the first annular portion 11. The first opposing region s1 is provided between the second annular portion 12 and the first region r1. The second region r2 is provided between the second annular portion 12 and the first annular portion 11. The second opposing region s2 is provided between the second annular portion 12 and the second region r2.

The first annular portion 11 includes a first cross position p1 that crosses the second radial direction Dr2. The second annular portion 12 includes a second cross position p2 that crosses the second radial direction Dr2. A first radial gap g1 is provided between the first cross position p1 and the second cross position p2, between the first region r1 and the second region r2, and between the first opposing region s1 and the second opposing region s2.

In the sensor 111, four independent electrode regions (first region r1, second region r2, first opposing region s1, and second opposing region s2) are provided in a region surrounded by the first connect portion 21, the third connect portion 23, the second annular portion 12 and the first annular portion 11. By these electrode regions, desired vibration in the second annular portion 12 and the first annular portion 11 can be obtained. Alternatively, the vibration state of the second annular portion 12 and the first annular portion 11 can be accurately detected. By using four independent electrode regions, for example, noise can be suppressed. High precision detection is possible. A sensor capable of improving characteristics can be provided. For example, the influence of noise included in the electrical signal applied to the fixed electrodes 30 can be suppressed.

The first region r1 and the second region r2 are on one circumferential direction Dc. The first opposing region s1 and the second opposing region s2 are on one circumferential direction Dc. The first opposing region s1 and the first region r1 are on one radial direction Dr. The second opposing region s2 and the second region r2 are on one radial direction Dr. These four independent electrode regions form one set. A plurality of sets may be arranged along the circumferential direction Dc. The first region r1, the second region r2, the first opposing region s1, and the second opposing region s2 have an arc shape extending along the circumferential direction Dc.

In the sensor 111, the connect portion 20 is not provided between the first cross position p1 and the second cross position p2. The movable portion 10M has high flexibility. Vibration can be effectively generated.

In the sensor 111, the plurality of connect portions 20 extend along the radial direction Dr.

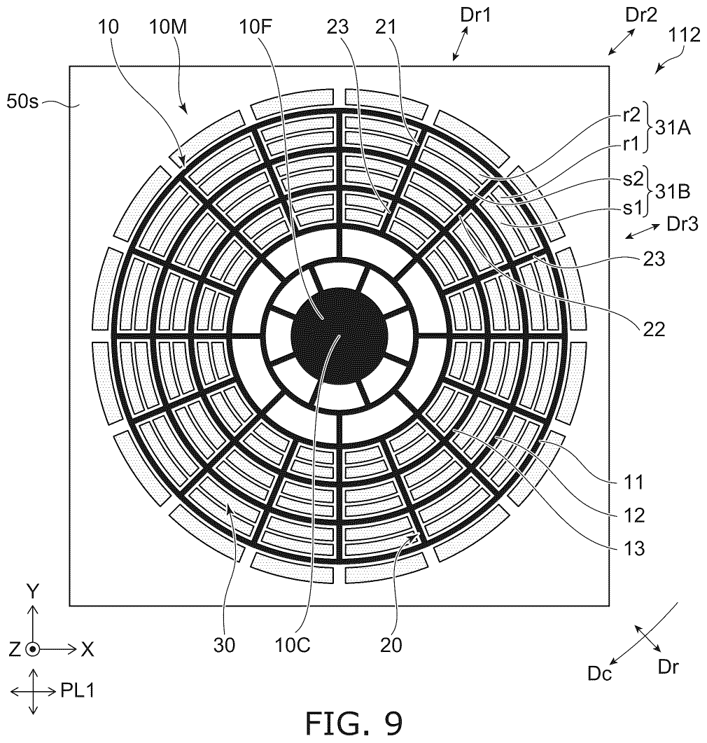

FIG. 9 is a schematic plan view illustrating a sensor according to the first embodiment.

As shown in FIG. 9, in a sensor 112 according to the embodiment, the configurations of the first fixed electrode 31A and the first opposing fixed electrode 31B are different from the configuration in the sensor 110. The configuration of the sensor 112 except for this may be the same as the configuration of the sensor 110.

The sensor 112 also includes the base 50s, the fixed portion 10F, the movable portion 10M, the first fixed electrode 31A, and the first opposing fixed electrode 31B. The first gap G1 is provided between the first face 50a of the base 50s and the movable portion 10M (see FIGS. 3 to 6). As shown in FIG. 9, the fixed portion 10F includes the first center 10C in the first plane PL1 parallel to the first face 50a.

In the sensor 112, the movable portion 10M includes the plurality of annular portions 10 and the plurality of connect portions 20. The plurality of annular portions 10 are provided around the fixed portion 10F with the first center 10C as the center. The plurality of annular portions 10 include the first annular portion 11, the second annular portion 12, and the third annular portion 13. The second annular portion 12 is provided between the fixed portion 10F and the first annular portion 11. The third annular portion 13 is provided between the fixed portion 10F and the second annular portion 12. The second annular portion 12 is next to the first annular portion 11. The third annular portion 13 is next to the second annular portion 12.

The plurality of connect portions 20 include the first connect portion 21 and the second connect portion 22. The first connect portion 21 and the second connect portion 22 are provided between the third annular portion 13 and the first annular portion 11. The first connect portion 21 and the second connect portion 22 connect the third annular portion 13, the second annular portion 12, and the first annular portion 11.

The first connect portion 21 is along the first radial direction Dr1. The first radial direction Dr1 passes through the first center 10C and is along the first plane PL1. The second connect portion 22 is along the second radial direction Dr2. The second radial direction Dr2 passes through the first center 10C and is along the first plane PL1. The second radial direction Dr2 crosses the first radial direction Dr1. For example, the second radial direction Dr2 is inclined with respect to the first radial direction Dr1.

The first fixed electrode 31A includes the first region r1 and the second region r2. The first opposing fixed electrode 31B includes the first opposing region s1 and the second opposing region s2. The first region r1 is provided between the second annular portion 12 and the first annular portion 11. The first opposing region s1 is provided between the second annular portion 12 and the first region r1. The second region r2 is provided between the second annular portion 12 and the first annular portion 11. The second opposing region s2 is provided between the second annular portion 12 and the second region r2. The second connect portion 22 passes between the first region r1 and the second region r2 and between the first opposing region s1 and the second opposing region s2.

In the sensor 112, three of the annular portions 10 are continuously connected by the first connect portion 21. The three of the annular portions 10 are continuously connected by the second connect portion 22. For example, it is easy to obtain a high intensity signal. By a high strength signal, noise is suppressed. In the sensor 112 as well, a sensor with improved characteristics can be provided.

The first region r1, the second region r2, the first opposing region s1, and the second opposing region s2 have an arc shape extending along the circumferential direction Dc.

In the sensor 112, the plurality of connect portions 20 may further include the third connect portion 23. The third connect portion 23 is provided between the third annular portion 13 and the first annular portion 11 and connects the third annular portion 13, the second annular portion 12, and the first annular portion 11. The third connect portion 23 is along the third radial direction Dr3. The third radial direction Dr3 passes through the first center 10C and extends along the first plane PL1. The third radial direction Dr3 crosses the first radial direction Dr1 and the second radial direction Dr2. The angle (first angle) between the second radial direction Dr2 and the first radial direction Dr1 is smaller than the angle (second angle) between the third radial direction Dr3 and the first radial direction Dr1. In this example, the first angle is substantially ½ of the second angle.

In the circumferential direction Dc, the first region r1 and the first opposing region s1 are provided between the first connect portion 21 and the second connect portion 22. The second region r2 and the second opposing region s2 are provided between the second connect portion 22 and the third connect portion 23.

In the sensor 112, the first region r1 and the second region r2 are on one circumferential direction Dc. The first opposing region s1 and the second opposing region s2 are on one circumferential direction Dc. The first opposing region s1 and the first region r1 are on one radial direction Dr. The second opposing region s2 and the second region r2 are on one radial direction Dr. These four independent electrode regions form one set. A plurality of sets may be arranged along the circumferential direction Dc.

FIG. 10 is a schematic plan view illustrating a sensor according to the first embodiment.

FIG. 10 illustrates the fixed portion 10F and the movable portion 10M. In a sensor 120 according to the embodiment, the movable portion 10M includes the first structure 41. For example, the first structure 41 is connected to the first annular portion 11. The first annular portion 11 is provided between the fixed portion 10F and the first structure 41. The first structure 41 functions as a mass body, for example. It becomes easier to obtain stable vibrations. For example, noise can be suppressed.

The movable portion 10M may include the second structure 42. The second structure 42 is provided between the fixed portion 10F and the first annular portion 11. The second structure 42 is connected to the first annular portion 11, for example. The second structure 42 may be connected to one of the plurality of connect portions 20. The second structure 42 functions as a mass body, for example. Noise is suppressed.

As shown in FIG. 10, the movable portion 10M may further include a first radial structure 28p. The first radial structure 28p is connected to one of the plurality of annular portions 10. In this example, the first radial structure 28p is connected to the fourth annular portion 14. The first radial structure 28p extends from the one of the plurality of annular portions 10 along the first radial direction Dr1. The first radial structure 28p is separated from another one of the plurality of annular portions 10 in the first radial direction Dr1. In this example, the first radial structure 28p is separated from a fifth annular portion 15 in the first radial direction Dr1. The other one of the plurality of annular portions 10 is next to the one of the plurality of annular portions 10 among the plurality of annular portions 10. The other one of the plurality of annular portions 10 is closest to the one of the plurality of annular portions 10 among the plurality of annular portions 10.

The movable portion 10M may further include a second radial structure 28q. The second radial structure 28q is connected to the one of the plurality of annular portions 10. The second radial structure 28q is connected to the fifth annular portion 15. The second radial structure 28q extends from the other one of the plurality of annular portions 10 toward the one of the plurality of annular portions 10 along the first radial direction Dr1. The second radial structure 28q extends from the fifth annular portion 15 toward the fourth annular portion 14 along the first radial direction Dr1. The second radial structure 28q is separated from the first radial structure 28p in the first radial direction Dr1.

By providing such a radial structure, the overall mass distribution can be made uniform without connect portions for the plurality of annular portions 10 being adjacent. It becomes easier to obtain higher characteristics. For example, the movable portion 10M can vibrate with an appropriate degree of freedom. Vibration with a stable state can be obtained. The signal strength based on the vibration becomes high. Highly sensitive detection becomes possible.

As shown in FIG. 10, the sensor 120 may include an inner structure 48. The inner structure 48 is fixed to the first face 50a. The fixed portion 10F is provided around the inner structure 48. Electrical connections may be made via the inner structure 48.

In this example, the inner structure 48 includes a first inner structure 48a and a second inner structure 48b. The inner structure 48 (for example, the first inner structure 48a and the second inner structure 48b) may be electrically insulated from the fixed portion 10F and the movable portion 10M. At least a part of the inner structure 48 (for example, the first inner structure 48a and the second inner structure 48b, etc.) is electrically connected to the fixed portion 10F or the movable portion 10M maybe connected by wiring for electrical connection.

In the sensor 120, the plurality of annular portions 10 include the first annular portion 11, the second annular portion 12, the third annular portion 13, the fourth annular portion 14, and the fifth annular portion 15. The number of the plurality of annular portions 10 is arbitrary.

### Second Embodiment

A second embodiment relates to an electronic device.

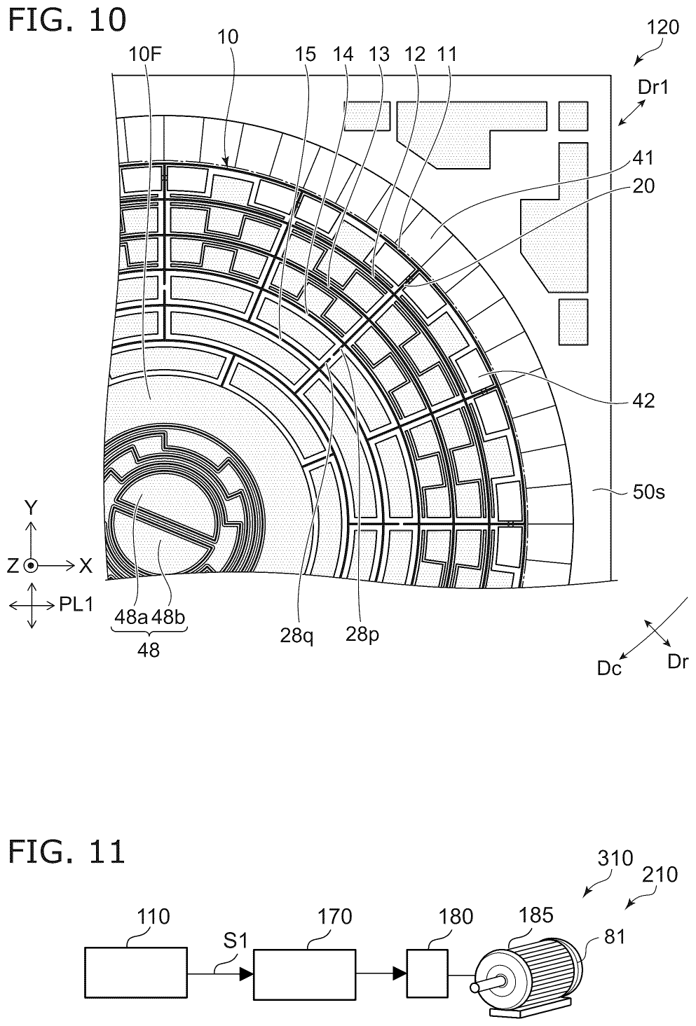

FIG. 11 is a schematic diagram illustrating an electronic device according to a second embodiment.

As shown in FIG. 11, an electronic device 310 according to the embodiment includes the sensors according to the first to third embodiments and the circuit processor 170. In the example of FIG. 11, the sensor 110 is drawn as the sensor. The circuit processor 170 is configured to control a circuit 180 based on the signal S1 obtained from the sensor. The circuit 180 is, for example, a control circuit for a drive device 185. According to the embodiment, for example, the circuit 180 for controlling the drive device 185 can be controlled with high accuracy.

As shown in FIG. 11, the sensor system 210 according to the embodiment includes the sensor (for example, the sensor 110) according to the first embodiment and a detection target member 81. The sensor 110 is fixed to the detection target member 81. The sensor 110 can detect a signal from the detection target member 81.

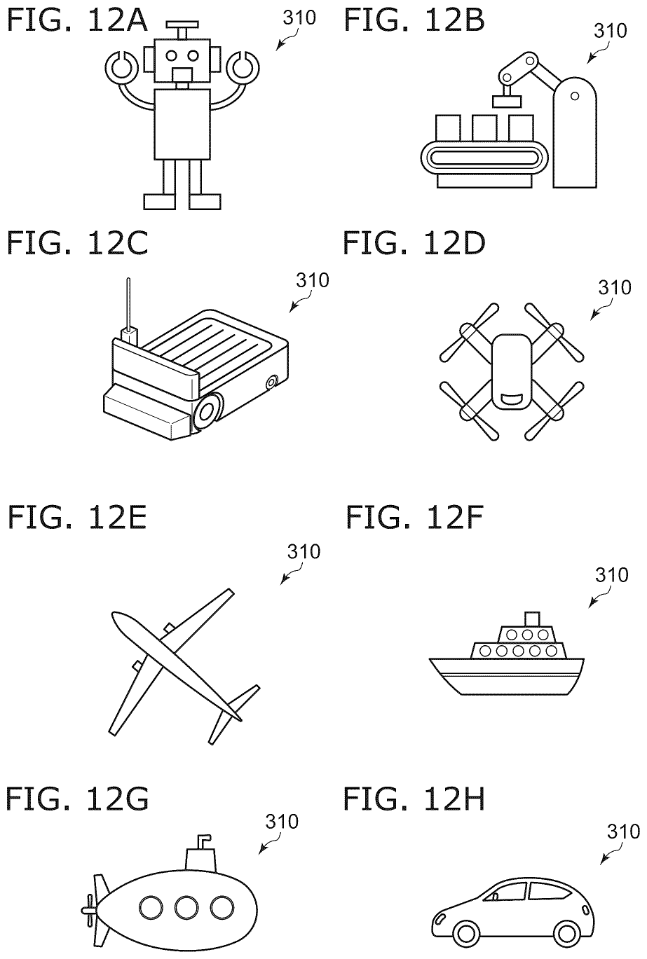

FIGS. 12A to 12H are schematic views illustrating applications of the electronic device according to the embodiment.

As shown in FIG. 12A, the electronic device 310 may be at least a portion of a robot. As shown in FIG. 12B, the electronic device 310 may be at least a portion of a machining robot provided in a manufacturing plant, etc. As shown in FIG. 12C, the electronic device 310 may be at least a portion of an automatic guided vehicle inside a plant, etc. As shown in FIG. 12D, the electronic device 310 may be at least a portion of a drone (an unmanned aircraft). As shown in FIG. 12E, the electronic device 310 may be at least a portion of an airplane. As shown in FIG. 12F, the electronic device 310 may be at least a portion of a ship. As shown in FIG. 12G, the electronic device 310 may be at least a portion of a submarine. As shown in FIG. 12H, the electronic device 310 may be at least a portion of an automobile. The electronic device 310 may include, for example, at least one of a robot or a moving body.

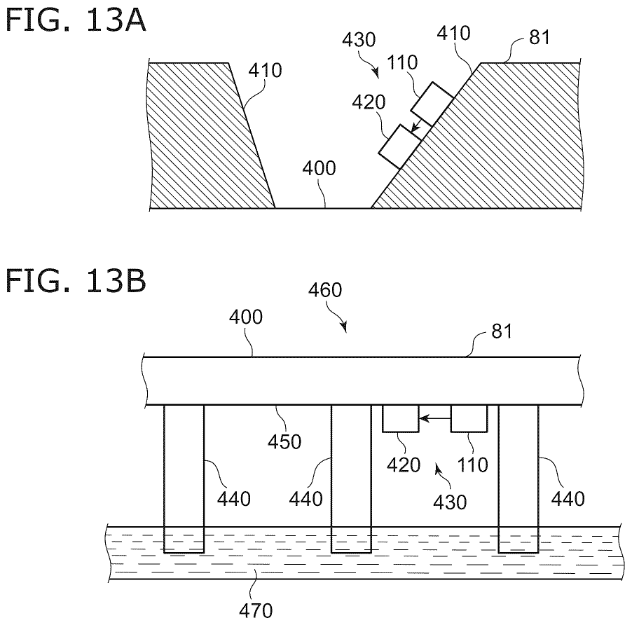

FIGS. 13A and 13B are schematic views illustrating applications of the sensor according to the embodiment.

As shown in FIG. 13A, a sensor 430 according to the fifth embodiment includes the sensor according to one of the first to third embodiments, and a transmission/reception part 420. In the example of FIG. 13A, the sensor 110 is illustrated as the sensor. The transmission/reception part 420 is configured to transmit the signal obtained from the sensor 110 by, for example, at least one of wireless and wired methods. The sensor 430 is provided on, for example, a slope surface 410 such as a road 400. The sensor 430 can monitor the state of, for example, a facility (e.g., infrastructure). The sensor 430 may be, for example, a state monitoring device.

For example, the sensor 430 detects a change in the state of a slope surface 410 of a road 400 with high accuracy. The change in the state of the slope surface 410 includes, for example, at least one of a change in the inclination angle and a change in the vibration state. The signal (inspection result) obtained from the sensor 110 is transmitted by the transmission/reception part 420. The status of a facility (e.g., infrastructure) can be monitored, for example, continuously.

As shown in FIG. 13B, the sensor 430 is provided, for example, in a portion of a bridge 460. The bridge 460 is provided above the river 470. For example, the bridge 460 includes at least one of a main girder 450 and a pier 440. The sensor 430 is provided on at least one of the main girder 450 and the pier 440. For example, at least one of the angles of the main girder 450 and the pier 440 may change due to deterioration or the like. For example, the vibration state may change in at least one of the main girder 450 and the pier 440. The sensor 430 detects these changes with high accuracy. The detection result can be transmitted to an arbitrary place by the transmission/reception part 420. Abnormalities can be detected effectively.

The embodiments may include the following Technical proposals:

### Technical Proposal 1

A sensor, comprising:
a base including a first face;
a fixed portion fixed to the first face;
a movable portion supported by the fixed portion;
a first fixed electrode; and
a first opposing fixed electrode,
a first gap being provided between the first face and the movable portion,
the fixed portion including a first center in a first plane parallel to the first face,
the movable portion including a first annular portion and a second annular portion,
the first fixed electrode including a first region and a second region,
the first opposing fixed electrode including a first opposing region and a second opposing region,
the first region being provided between the second annular portion and the first annular portion,
the first opposing region being provided between the second annular portion and the first region,
the second region being provided between the second annular portion and the first annular portion,
the second opposing region being provided between the second annular portion and the second region,
a first region width of the first region in a radial direction being different from a second region width of the second region in the radial direction, the radial direction being parallel to the first plane and passing through the first center, and
a first opposing region width of the first opposing region in the radial direction being different from a second opposing region width of the second opposing region in the radial direction.

### Technical Proposal 2

The sensor according to Technical proposal 1, wherein
one of a first condition and a second condition is satisfied,
in the first condition, the first region width is wider than the second region width, and the first opposing region width is narrower than the second opposing region width, and
in the second condition, the first region width is narrower than the second region width, and the first opposing region width is wider than the second opposing region width.

### Technical Proposal 3

The sensor according to Technical proposal 1 or 2, wherein
the second region is continuous with the first region, and
the second opposing region is continuous with the first opposing region.

### Technical Proposal 4

The sensor according to any one of Technical proposals 1-3, wherein
a direction from the second opposing region to the first region is along a circumferential direction centered on the first center.

### Technical Proposal 5

The sensor according to Technical proposal 1, wherein
the first fixed electrode further includes a third region,
the first opposing fixed electrode further includes a third opposing region,
the third region is provided between the second annular portion and the first annular portion,
at least a part of the third opposing region is provided between the second annular portion and the third region,
the first opposing region is provided between the second opposing region and the third opposing region,
the first region width is different from a third region width of the third region in the radial direction, and
the first opposing region width is different from a third opposing region width of the third opposing region in the radial direction.

### Technical Proposal 6

The sensor according to Technical proposal 5, wherein
the first region width is wider than the second region width,
the first opposing region width is narrower than the second opposing region width,
the first region width is wider than the third region width, and
the first opposing region width is narrower than the third opposing region width.

### Technical Proposal 7

The sensor according to Technical proposal 5 or 6, wherein
in a circumferential direction centered on the first center, at least a part of the first region is provided between the second region and the third region, and
in the circumferential direction, at least a part of the first opposing region is provided between the second opposing region and the third opposing region.

### Technical Proposal 8

The sensor according to Technical proposal 5 or 6, wherein
a second opposing region length of the second opposing region in a circumferential direction centered on the first center is not less than 0.8 times and not more than 1.2 times of a third opposing region length of the third opposing region in the circumferential direction.

### Technical Proposal 9

The sensor according to Technical proposal 8, wherein a first region length of the first region in the circumferential direction is not less than 0.1 times and not more than 10 times of the second opposing region length.

### Technical Proposal 10

The sensor according to Technical proposal 1, wherein
a first ratio of a first absolute value of a difference between the first region width and the second region width to the first region width is not less than 0.9 and not more than 30, and
a second ratio of a second absolute value of a difference between the first opposing region width and the second opposing region width to the first opposing region width is not less than 0.9 and not more than 30.

### Technical Proposal 11

The sensor according to any one of Technical proposals 1-10, wherein
the movable portion includes a plurality of first connect portions extending along the radial direction,
the plurality of first connect portions connect the first annular portion and the second annular portion,
the first fixed electrode and the first opposing fixed electrode are provided between one of the plurality of first connect portions and another one of the plurality of first connect portions, and
the other one of the plurality of first connect portions is next to the one of the plurality of first connect portions.

### Technical Proposal 12

The sensor according to Technical proposal 1, further comprising:
a second fixed electrode; and
a second opposing fixed electrode,
the movable portion further including a third annular portion,
the second annular portion being provided between the third annular portion and the first annular portion,
the second fixed electrode including a fourth region and a fifth region,
the second opposing fixed electrode including a fourth opposing region and a fifth opposing region,
the fourth region being provided between the third annular portion and the second annular portion,
the fourth opposing region being provided between the third annular portion and the fourth region,
the fifth region being provided between the third annular portion and the second annular portion,
the fifth opposing region being provided between the third annular portion and the fifth region,
a fourth region width of the fourth region in the radial direction being different from a fifth region width of the fifth region in the radial direction, and
a fourth opposing region width of the fourth opposing region in the radial direction being different from a fifth opposing region width of the fifth opposing region in the radial direction.

### Technical Proposal 13

The sensor according to Technical proposal 12, wherein
the first region width is wider than the second region width,
the first opposing region width is narrower than the second opposing region width,
the fourth region width is narrower than the fifth region width, and
the fourth opposing region width is wider than the fifth opposing region width.

### Technical Proposal 14

The sensor according to Technical proposal 12, wherein
the second fixed electrode further includes a sixth region,
the second opposing fixed electrode further includes a sixth opposing region,
the sixth region is provided between the third annular portion and the second annular portion,
at least a part of the sixth opposing region is provided between the third annular portion and the sixth region,
at least a part of the fourth region is provided between the fifth region and the sixth region,
the fourth region width is different from a sixth region width of the sixth region in the radial direction, and
the fourth opposing region width is different from a sixth opposing region width of the sixth opposing region in the radial direction.

### Technical Proposal 15

The sensor according to Technical proposal 14, wherein
the first region width is wider than the second region width,
the first opposing region width is narrower than the second opposing region width,
the fourth region width is narrower than the fifth region width,
the fourth opposing region width is wider than the fifth opposing region width,
the fourth region width is narrower than the fifth region width,
the fourth opposing region width is wider than the fifth opposing region width,
the fourth region width is narrower than the sixth region width, and
the fourth opposing region width is wider than the sixth opposing region width.

### Technical Proposal 16

The sensor according to Technical proposal 15, wherein
the fifth region is provided between the fifth opposing region and the second region, and
the second opposing region is provided between the fifth region and the second region.

### Technical Proposal 17

A sensor, comprising:
a base including a first face;
a fixed portion fixed to the first face;
a movable portion supported by the fixed portion;
a first fixed electrode; and
a first opposing fixed electrode,
a first gap being provided between the first face and the movable portion,
the fixed portion including a first center in a first plane parallel to the first face,
the movable portion including a plurality of annular portions and a plurality of connect portions,
the plurality of annular portions being provided around the fixed portion with the first center as a center,
the plurality of annular portions including a first annular portion, a second annular portion provided between the fixed portion and the first annular portion, and a third annular portion provided between the fixed portion and the second annular portion,
the plurality of connect portions including a first connect portion, a second connect portion, and a third connect portion,
the first connect portion being provided between the second annular portion and the first annular portion, and connecting the second annular portion and the first annular portion,
the first connect portion being along a first radial direction passing through the first center and along the first plane,
the second connect portion being provided between the third annular portion and the second annular portion, and connecting the third annular portion and the second annular portion,
the second connect portion being along a second radial direction passing through the first center and along the first plane,
the third connect portion being provided between the second annular portion and the first annular portion, and connecting the second annular portion and the first annular portion,
the third connect portion being along a third radial direction passing through the first center and along the first plane,
the second radial direction crossing the first radial direction,
the third radial direction crossing the first radial direction and the second radial direction,
a first angle between the second radial direction and the first radial direction being smaller than a second angle between the third radial direction and the first radial direction,
the first fixed electrode including a first region and a second region,
the first opposing fixed electrode including a first opposing region and a second opposing region,
the first region being provided between the second annular portion and the first annular portion,
the first opposing region being provided between the second annular portion and the first region,
the second region being provided between the second annular portion and the first annular portion,
the second opposing region being provided between the second annular portion and the second region,
the first annular portion including a first cross position crossing the second radial direction,
the second annular portion including a second cross position crossing the second radial direction, and
a first radial gap being provided between the first cross position and the second cross position, between the first region and the second region, and between the first opposing region and the second opposing region.

### Technical Proposal 18

A sensor, comprising:
a base including a first face;
a fixed portion fixed to the first face;
a movable portion supported by the fixed portion;
a first fixed electrode; and
a first opposing fixed electrode,
a first gap being provided between the first face and the movable portion,
the fixed portion including a first center in a first plane parallel to the first face,
the movable portion including a plurality of annular portions and a plurality of connect portions,
the plurality of annular portions being provided around the fixed portion with the first center as a center,
the plurality of annular portions including a first annular portion, a second annular portion provided between the fixed portion and the first annular portion, and a third annular portion provided between the fixed portion and the second annular portion,
the plurality of connect portions including a first connect portion and a second connect portion,
the first connect portion and the second connect portion being provided between the third annular portion and the first annular portion, the first connect portion and the second connect portion connecting the third annular portion, the second annular portion, and the first annular portion,
the first connect portion being along a first radial direction passing through the first center and along the first plane,
the second connect portion being along a second radial direction passing through the first center and along the first plane,
the second radial direction crossing the first radial direction,
the first fixed electrode including a first region and a second region,
the first opposing fixed electrode including a first opposing region and a second opposing region,
the first region being provided between the second annular portion and the first annular portion,
the first opposing region being provided between the second annular portion and the first region,
the second region being provided between the second annular portion and the first annular portion,
the second opposing region being provided between the second annular portion and the second region, and
the second connect portion passing between the first region and the second region and between the first opposing region and the second opposing region.

### Technical Proposal 19

A sensor system, comprising:
the sensor according to any one of Technical proposals 1-18; and
a detection target member, the sensor being fixed to the detection target member.

### Technical Proposal 20

An electronic device, comprising:
the sensor according to any one of Technical proposals 1-18; and
a circuit controller configured to control a circuit based on a signal obtained from the sensor.

According to the embodiment, a sensor, a sensor system, and an electronic device whose characteristics can be improved can be provided.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the sensor such as members, substrates, sensor sections, housings, sensor elements, bases, fixed portions, movable portions, controllers, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all sensors, all sensor systems, and all electronic devices practicable by an appropriate design modification by one skilled in the art based on the sensors, the sensor systems, and the electronic devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A sensor, comprising:
a base including a first face;
a fixed portion fixed to the first face;
a movable portion supported by the fixed portion;
a first fixed electrode; and
a first opposing fixed electrode,
a first gap being provided between the first face and the movable portion,
the fixed portion including a first center in a first plane parallel to the first face,
the movable portion including a first annular portion and a second annular portion,
the first fixed electrode including a first region and a second region,
the first opposing fixed electrode including a first opposing region and a second opposing region,
the first region being provided between the second annular portion and the first annular portion,
the first opposing region being provided between the second annular portion and the first region,
the second region being provided between the second annular portion and the first annular portion,
the second opposing region being provided between the second annular portion and the second region,
a first region width of the first region in a radial direction being different from a second region width of the second region in the radial direction, the radial direction being parallel to the first plane and passing through the first center, and
a first opposing region width of the first opposing region in the radial direction being different from a second opposing region width of the second opposing region in the radial direction.

2. The sensor according to claim 1, wherein
one of a first condition and a second condition is satisfied,
in the first condition, the first region width is wider than the second region width, and the first opposing region width is narrower than the second opposing region width, and
in the second condition, the first region width is narrower than the second region width, and the first opposing region width is wider than the second opposing region width.

3. The sensor according to claim 1, wherein
the second region is continuous with the first region, and
the second opposing region is continuous with the first opposing region.

4. The sensor according to claim 1, wherein
a direction from the second opposing region to the first region is along a circumferential direction centered on the first center.

5. The sensor according to claim 1, wherein
the first fixed electrode further includes a third region,
the first opposing fixed electrode further includes a third opposing region,
the third region is provided between the second annular portion and the first annular portion,
at least a part of the third opposing region is provided between the second annular portion and the third region,
the first opposing region is provided between the second opposing region and the third opposing region,
the first region width is different from a third region width of the third region in the radial direction, and
the first opposing region width is different from a third opposing region width of the third opposing region in the radial direction.

6. The sensor according to claim 5, wherein
the first region width is wider than the second region width,
the first opposing region width is narrower than the second opposing region width,
the first region width is wider than the third region width, and
the first opposing region width is narrower than the third opposing region width.

7. The sensor according to claim 5, wherein
in a circumferential direction centered on the first center, at least a part of the first region is provided between the second region and the third region, and
in the circumferential direction, at least a part of the first opposing region is provided between the second opposing region and the third opposing region.

8. The sensor according to claim 5, wherein
a second opposing region length of the second opposing region in a circumferential direction centered on the first center is not less than 0.8 times and not more than 1.2 times of a third opposing region length of the third opposing region in the circumferential direction.

9. The sensor according to claim 8, wherein
a first region length of the first region in the circumferential direction is not less than 0.1 times and not more than 10 times of the second opposing region length.

10. The sensor according to claim 1, wherein
a first ratio of a first absolute value of a difference between the first region width and the second region width to the first region width is not less than 0.9 and not more than 30, and
a second ratio of a second absolute value of a difference between the first opposing region width and the second opposing region width to the first opposing region width is not less than 0.9 and not more than 30.

11. The sensor according to claim 1, wherein
the movable portion includes a plurality of first connect portions extending along the radial direction,
the plurality of first connect portions connect the first annular portion and the second annular portion,
the first fixed electrode and the first opposing fixed electrode are provided between one of the plurality of first connect portions and another one of the plurality of first connect portions, and
the other one of the plurality of first connect portions is next to the one of the plurality of first connect portions.

12. The sensor according to claim 1, further comprising:
a second fixed electrode; and
a second opposing fixed electrode,
the movable portion further including a third annular portion,
the second annular portion being provided between the third annular portion and the first annular portion,
the second fixed electrode including a fourth region and a fifth region,
the second opposing fixed electrode including a fourth opposing region and a fifth opposing region,
the fourth region being provided between the third annular portion and the second annular portion,
the fourth opposing region being provided between the third annular portion and the fourth region,
the fifth region being provided between the third annular portion and the second annular portion,
the fifth opposing region being provided between the third annular portion and the fifth region,
a fourth region width of the fourth region in the radial direction being different from a fifth region width of the fifth region in the radial direction, and
a fourth opposing region width of the fourth opposing region in the radial direction being different from a fifth opposing region width of the fifth opposing region in the radial direction.

13. The sensor according to claim 12, wherein
the first region width is wider than the second region width,
the first opposing region width is narrower than the second opposing region width,
the fourth region width is narrower than the fifth region width, and
the fourth opposing region width is wider than the fifth opposing region width.

14. The sensor according to claim 12, wherein
the second fixed electrode further includes a sixth region,
the second opposing fixed electrode further includes a sixth opposing region,
the sixth region is provided between the third annular portion and the second annular portion,
at least a part of the sixth opposing region is provided between the third annular portion and the sixth region,
at least a part of the fourth region is provided between the fifth region and the sixth region,
the fourth region width is different from a sixth region width of the sixth region in the radial direction, and
the fourth opposing region width is different from a sixth opposing region width of the sixth opposing region in the radial direction.

15. The sensor according to claim 14, wherein
the first region width is wider than the second region width,
the first opposing region width is narrower than the second opposing region width,
the fourth region width is narrower than the fifth region width,
the fourth opposing region width is wider than the fifth opposing region width,
the fourth region width is narrower than the fifth region width,
the fourth opposing region width is wider than the fifth opposing region width,
the fourth region width is narrower than the sixth region width, and
the fourth opposing region width is wider than the sixth opposing region width.

16. The sensor according to claim 15, wherein
the fifth region is provided between the fifth opposing region and the second region, and
the second opposing region is provided between the fifth region and the second region.

17. A sensor, comprising:
a base including a first face;
a fixed portion fixed to the first face;
a movable portion supported by the fixed portion;
a first fixed electrode; and
a first opposing fixed electrode,
a first gap being provided between the first face and the movable portion,
the fixed portion including a first center in a first plane parallel to the first face,
the movable portion including a plurality of annular portions and a plurality of connect portions,
the plurality of annular portions being provided around the fixed portion with the first center as a center,
the plurality of annular portions including a first annular portion, a second annular portion provided between the fixed portion and the first annular portion, and a third annular portion provided between the fixed portion and the second annular portion,
the plurality of connect portions including a first connect portion, a second connect portion, and a third connect portion,
the first connect portion being provided between the second annular portion and the first annular portion, and connecting the second annular portion and the first annular portion,
the first connect portion being along a first radial direction passing through the first center and along the first plane,
the second connect portion being provided between the third annular portion and the second annular portion, and connecting the third annular portion and the second annular portion,
the second connect portion being along a second radial direction passing through the first center and along the first plane,
the third connect portion being provided between the second annular portion and the first annular portion, and connecting the second annular portion and the first annular portion,
the third connect portion being along a third radial direction passing through the first center and along the first plane,
the second radial direction crossing the first radial direction,
the third radial direction crossing the first radial direction and the second radial direction,
a first angle between the second radial direction and the first radial direction being smaller than a second angle between the third radial direction and the first radial direction,
the first fixed electrode including a first region and a second region,
the first opposing fixed electrode including a first opposing region and a second opposing region,
the first region being provided between the second annular portion and the first annular portion,
the first opposing region being provided between the second annular portion and the first region,
the second region being provided between the second annular portion and the first annular portion,
the second opposing region being provided between the second annular portion and the second region,
the first annular portion including a first cross position crossing the second radial direction,
the second annular portion including a second cross position crossing the second radial direction, and
a first radial gap being provided between the first cross position and the second cross position, between the first region and the second region, and between the first opposing region and the second opposing region.

18. A sensor, comprising:
a base including a first face;
a fixed portion fixed to the first face;
a movable portion supported by the fixed portion;
a first fixed electrode; and
a first opposing fixed electrode,
a first gap being provided between the first face and the movable portion,
the fixed portion including a first center in a first plane parallel to the first face,
the movable portion including a plurality of annular portions and a plurality of connect portions,
the plurality of annular portions being provided around the fixed portion with the first center as a center,
the plurality of annular portions including a first annular portion, a second annular portion provided between the fixed portion and the first annular portion, and a third annular portion provided between the fixed portion and the second annular portion,
the plurality of connect portions including a first connect portion and a second connect portion,
the first connect portion and the second connect portion being provided between the third annular portion and the first annular portion, the first connect portion and the second connect portion connecting the third annular portion, the second annular portion, and the first annular portion,
the first connect portion being along a first radial direction passing through the first center and along the first plane,
the second connect portion being along a second radial direction passing through the first center and along the first plane,
the second radial direction crossing the first radial direction,
the first fixed electrode including a first region and a second region,
the first opposing fixed electrode including a first opposing region and a second opposing region,
the first region being provided between the second annular portion and the first annular portion,
the first opposing region being provided between the second annular portion and the first region,
the second region being provided between the second annular portion and the first annular portion,
the second opposing region being provided between the second annular portion and the second region, and
the second connect portion passing between the first region and the second region and between the first opposing region and the second opposing region.

19. A sensor system, comprising:
the sensor according to claim 1; and
a detection target member, the sensor being fixed to the detection target member.

20. An electronic device, comprising:
the sensor according to claim 1; and
a circuit controller configured to control a circuit based on a signal obtained from the sensor.
